(19) United States
(12) Patent Application Publication
(10) Pub. No.: US 2026/0297745 A1
(43) Pub. Date: Oct. 1, 2026

(54) PLASMA ENHANCED VAPOR DEPOSITION METHODS AND SYSTEMS FOR FORMING LOW-K MATERIAL FILMS

(71) Applicant: ASM IP Holding B.V., Almere (NL)

(72) Inventors: Paul Chatelain, Tokyo (JP); Jerome Samuel Nicolas, Tokyo (JP)

(21) Appl. No.: 19/629,795

(22) Filed: Mar. 26, 2026

Related U.S. Application Data
(60) Provisional application No. 63/780,659, filed on Mar. 31, 2025.

(51) Int. Cl. C23C 16/455; C01B 21/082; C01B 32/907; C23C 16/56

(52) U.S. Cl. CPC C23C 16/45538; C01B 21/0828; C01B 32/907; C23C 16/45542; C23C 16/56

(57) ABSTRACT

Plasma enhanced vapor deposition methods for forming a low-k material layer on a surface of a substrate are disclosed. Exemplary methods comprise providing a substrate in a reaction chamber, providing a hydrogen source to the reaction chamber, providing a plasma to the reaction chamber, and providing a Si-precursor to the reaction chamber. The Si-precursor comprises at least one silicon atom that is bonded to an oxygen atom and to an optionally substituted vinyl group. Systems for performing the plasma enhanced vapor deposition methods are also disclosed.

### CROSS-REFERENCE TO RELATED APPLICATIONS

This application claims priority to U.S. Provisional Patent Application Ser. No. 63/780,659 filed Marh 31, 2025 and titled PLASMA ENHANCED VAPOR DEPOSITION METHODS AND SYSTEMS FOR FORMING LOW-K MATERIAL FILMS, the disclosure of which is hereby incorporated by reference in its entirety.

### FIELD

The present disclosure generally relates to the field of semiconductor processing methods and systems. In particular, the present disclosure relates to compositions, methods, and systems for forming low-k dielectric material films on a surface of a substrate.

### BACKGROUND

Low-k dielectric films are essential materials in semiconductor manufacturing, primarily used to reduce parasitic capacitance between metal interconnects. These films have a lower dielectric constant (k) compared to traditional silicon dioxide, which helps minimize signal delay and power consumption in integrated circuits. As device dimensions continue to shrink, there is a need for low-k materials that can further reduce resistance-capacitance (RC) delay, crosstalk, and heat generation. Such low-k materials must also have sufficient thermal stability, mechanical strength, and chemical resistance to be compatible with subsequent processing steps during device integration.

Silicon oxycarbide (SiOC) has gained interest for use as a low-k material, for example, as gate spacers in logic devices and bit line spacers in memory devices. Plasma-enhanced vapor deposition methods have been employed to deposit SiOC films. However, formation of SiOC material films with a desired deposition rate, dielectric constant, wet etch ratio, and conformality has been challenging and, often times, attempts to improve one or more of these properties results in a negative impact in one or more of the other properties.

Precursor selection may be a means to improve vapor deposition methods. Suitable precursors must have sufficient volatility, thermal stability, and reactivity to ensure efficient material deposition. Further, since the precursor is the source material that reacts to form the SiOC film, its composition can directly impact the properties of the film. For example, precursors that lead to increased carbon content in the SiOC material film may lead to a lower k value and reduced wet etching rate. In this regard, the present disclosure is related to precursors and to method and systems for using said precursors to form SiOC films that may address and meet many of these needs.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to film forming compositions that are configured for forming low-k material films and to methods and systems for using said compositions to form low-k material films. In some embodiments, the low-k material film comprises silicon oxycarbide (SiOC) or silicon oxycarbon nitride (SiOCN).

An aspect of the present disclosure relates to film forming compositions that are configured to deposit a low-k material film. The film forming compositions comprise a Si-precursor that comprises at least one silicon atom that is bonded to an oxygen atom and to an optionally substituted vinyl group.

In some embodiments, the Si-precursor has a structure according to general formula (1):

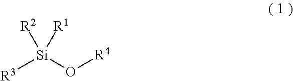

wherein R1 is the optionally substituted vinyl group; R2 is selected from the group consisting of an H atom, a C1-C6 alkyl group, and a second optionally substituted vinyl group; R3 is selected from the group consisting of an H atom and a C1-C6 alkyl group; and R4 is selected from the group consisting of a C1-C6 alkyl group and a C2-C6 alkenyl group. In some of these embodiments, one or both of R2 and R3 is an H atom. In some of these embodiments, R2 is selected from the group consisting of an H atom and a C1-C6 alkyl group; R3 is an H atom; and R4 is a C1-C6 alkyl group.

In some embodiments, the Si-precursor having a structure according to general formula (1) is selected from the group consisting of ethenylmethoxysilane, ethenylethoxysilane, ethenylmethoxymethylsilane, ethenylethoxymethylsilane, ethenylethoxyethylsilane, ethenylethoxydimethylsilane, ethenylethoxydiethylsilane, diethenylmethoxysilane, diethenylethoxysilane, diethenylmethoxymethylsilane, and diethenylethoxymethylsilane. In some other embodiments, the Si-precursor has a structure according to general formula (2):

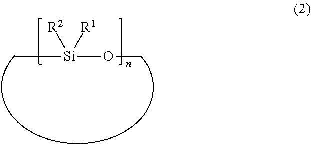

wherein n is an integer selected from 2, 3, 4, or 5; each R1 is independently the optionally substituted vinyl group; and each R2 is independently selected from the group consisting of an H atom, a C1-C6 alkyl group, and a second optionally substituted vinyl group. In certain embodiments, each R1 is the optionally substituted vinyl group and each R2 is a C1-C6 alkyl group.

In some of these embodiments, the Si-precursor having a structure according to general formula (2) has a four membered ring structure (i.e., n=2). In some other of these embodiments, the Si-precursor having a structure according to general formula (2) has a six membered ring structure (i.e., n=3). In yet some other of these embodiments, the Si-precursor having a structure according to general formula (2) has an eight membered ring structure (i.e., n=4). In yet some other of these embodiments, the Si-precursor having a structure according to general formula (2) has a ten membered ring structure (i.e., n=5).

In some of these embodiments, the Si-precursor having a structure according to general formula (2) is selected from the group consisting of 1,3-divinylcyclodisiloxane, 1,3-dimethyl-1,3-divinylcyclodisiloxane, 1,3-diethyl-1,3-divinylcyclodisiloxane, 1,1,3,3-tetravinylcyclodisiloxane, 1,3,5-trivinylcyclotrisiloxane, 1,3,5-trimethyl-1,3,5-trivinylcyclotrisiloxane, 1,3,5-triethyl-1,3,5-trivinylcyclotrisiloxane, 1,1,3,3,5,5-hexavinylcyclotrisiloxane, 1,3,5,7-tetravinylcyclotetrasiloxane, 1,3,5,7-tetramethyl-1,3,5,7-tetravinylcyclotetrasiloxane, 1,3,5,7-tetraethyl-1,3,5,7-tetravinylcyclotetrasiloxane, 1,1,3,3,5,5,7,7-octavinylcyclotetrasiloxane, 1,3,5,7,9-pentavinylcyclopentasiloxane, 1,3,5,7,9-pentamethyl-1,3,5,7,9-pentavinylcyclopentasiloxane, 1,3,5,7,9-pentaethyl-1,3,5,7,9-pentavinylcyclopentasiloxane, and 1,1,3,3,5,5,7,7,9,9-decavinylcyclopentasiloxane.

In some embodiments, the film forming composition has a purity of 95 wt. % or more (based on the weight of the Si-precursor). In some embodiments, the film forming composition has a purity of about 95 wt. % or more, or about 97 wt. % or more, about 98 wt. % or more, about 99 wt. % or more, about 99.5 wt. % or more, about 99.9 wt. % or more, about 99.99 wt. % or more, or about 99.999 wt. % or more, or even about 99.9999 wt. % (based on the weight of the Si-precursor).

Another aspect of the present disclosure relates to precursor delivery vessels that comprises the film forming composition comprising the Si-precursor described in any of the above paragraphs. The precursor delivery vessel comprises an outer wall that encloses a cavity for storing the film forming composition and an outlet for allowing a flow of the film forming composition to exit the cavity. The outlet is seated in the outer wall of the precursor delivery vessel and is in communication with the cavity of the precursor delivery vessel and has at least one valve positioned thereon to fluidly couple or decouple the cavity to the outside environment.

Another aspect of the disclosure relates to a method of forming a low-k material film on a surface of a substrate using the film forming composition comprising the Si-precursor described in the above related paragraphs. The method comprises providing a substrate in a reaction chamber; and forming a low-k material layer on the surface of the substrate using a vapor deposition process. The vapor deposition process comprises optionally providing an hydrogen source to the reaction chamber, providing a Si-precursor to the reaction chamber, wherein the Si-precursor comprises at least one silicon atom that is bonded to an oxygen atom and to an optionally substituted vinyl group; and providing a plasma to the reaction chamber.

In some embodiments, the Si precursor has a structure according to general formula (1):

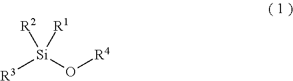

wherein R1 is the optionally substituted vinyl group; R2 is selected from the group consisting of an H atom, a C1-C6 alkyl group, and a second optionally substituted vinyl group; R3 is selected from the group consisting of an H atom and a C1-C6 alkyl group; and R4 is selected from the group consisting of a C1-C6 alkyl group and a C2-C6 alkenyl group. In some of these embodiments, R2 is selected from the group consisting of an H atom, a C1-C6 alkyl group; R3 is an H atom; and R4 is a C1-C6 alkyl group. In some of these embodiments, R2 is selected from the group consisting of an H atom and a C1-C6 alkyl group; R3 is an H atom; and R4 is a C1-C6 alkyl group. In some of these embodiments, one or both of R2 and R3 is an H atom.

In some embodiments, the Si-precursor having a structure according to general formula (1) is selected from the group consisting of ethenylmethoxysilane, ethenylethoxysilane, ethenylmethoxymethylsilane, ethenylethoxymethylsilane, ethenylethoxyethylsilane, ethenylethoxydimethylsilane, ethenylethoxydiethylsilane, diethenylmethoxysilane, diethenylethoxysilane, diethenylmethoxymethylsilane, and diethenylethoxymethylsilane. In other embodiments, the Si precursor has a structure according to general formula (2):

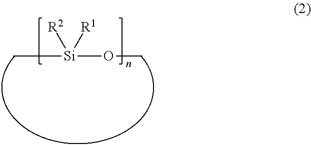

wherein n is an integer selected from 2, 3, 4, or 5; each R1 is independently the optionally substituted vinyl group; and each R2 is independently selected from the group consisting of an H atom, a C1-C6 alkyl group, and a second optionally substituted vinyl group. In certain embodiments, each R1 is the optionally substituted vinyl group and each R2 is a C1-C6 alkyl group.

In some of these embodiments, the Si-precursor having a structure according to general formula (2) has a four membered ring structure (i.e., n=2). In some other of these embodiments, the Si-precursor having a structure according to general formula (2) has a six membered ring structure (i.e., n=3). In yet some other of these embodiments, the Si-precursor having a structure according to general formula (2) has an eight membered ring structure (i.e., n=4). In yet some other of these embodiments, the Si-precursor having a structure according to general formula (2) has a ten membered ring structure (i.e., n=5).

In some of these embodiments, the Si-precursor having a structure according to general formula (2) is selected from the group consisting of 1,3-divinylcyclodisiloxane, 1,3-dimethyl-1,3-divinylcyclodisiloxane, 1,3-diethyl-1,3-divinylcyclodisiloxane, 1,1,3,3-tetravinylcyclodisiloxane, 1,3,5-trivinylcyclotrisiloxane, 1,3,5-trimethyl-1,3,5-trivinylcyclotrisiloxane, 1,3,5-triethyl-1,3,5-trivinylcyclotrisiloxane, 1,1,3,3,5,5-hexavinylcyclotrisiloxane, 1,3,5,7-tetravinylcyclotetrasiloxane, 1,3,5,7-tetramethyl-1,3,5,7-tetravinylcyclotetrasiloxane, 1,3,5,7-tetraethyl-1,3,5,7-tetravinylcyclotetrasiloxane, 1,1,3,3,5,5,7,7-octavinylcyclotetrasiloxane, 1,3,5,7,9-pentavinylcyclopentasiloxane, 1,3,5,7,9-pentamethyl-1,3,5,7,9-pentavinylcyclopentasiloxane, 1,3,5,7,9-pentaethyl-1,3,5,7,9-pentavinylcyclopentasiloxane, and 1,1,3,3,5,5,7,7,9,9-decavinylcyclopentasiloxane.

In some embodiments, where the hydrogen source is provided to the reaction chamber, the hydrogen source comprises one or more of hydrogen (H2), an N—H bond containing reactant, and an Si—H bond containing reactant.

In some embodiments, where the hydrogen source is provided to the reaction chamber, the hydrogen source comprises hydrogen (H2) gas or a mixture of hydrogen gas and an inert gas. The hydrogen source may comprise a mixture of H2 and a noble gas.

In some embodiments, where the hydrogen source is provided to the reaction chamber, the hydrogen source comprises a N—H bond containing reactant. The hydrogen source may comprise one or more of ammonia (NH3), hydrazine (N2H2), a substituted hydrazine, and a mixture of hydrogen and nitrogen (H2/N2).

In some embodiments, where the hydrogen source is provided to the reaction chamber, the hydrogen source comprises a Si—H bond containing reactant. The hydrogen source may comprise one or more of a silane, a halosilane, a silanol, and an alkoxysilane.

In some embodiments, the vapor deposition process is a cyclic deposition process, wherein the step of providing the Si-precursor to the reaction chamber comprises pulsing the Si-precursor into the reaction chamber.

In some embodiments, the step of providing the Si-precursor to the reaction chamber at least partially overlaps with the step of providing the plasma to the reaction chamber. In other embodiments, the step of providing the Si-precursor to the reaction chamber is separate from the step of providing the plasma to the reaction chamber.

In some embodiments, where the hydrogen source is provided to the reaction chamber, the step of providing the hydrogen source to the reaction chamber at least partially overlaps with the step of providing the plasma to the reaction chamber.

In some embodiments, the plasma is a remote plasma. In some of these embodiments, the plasma is an inductively coupled plasma (ICP).

In some embodiments, the method further comprises maintaining a temperature of the substrate at least about 50° C. and no more than about 500° C., preferably at least about 75° C. and no more than about 250° C., preferably at least about 100° C. and no more than about 200° C.

In some embodiments, the method further comprises maintaining the reaction chamber at a pressure of at least about 0.5 Torr and no more than about 100 Torr, preferably at least about 1 Torr and no more than about 10 Torr, or preferably at least about 2 Torr and no more than about 5 Torr.

In some embodiments, the method further comprises, after the vapor deposition process, one or more of irradiating the low k material layer with UV radiation, treating the low k material layer with a plasma, and annealing the low k material layer.

Another aspect of the disclosure relates to a substrate processing apparatus for forming a low-k material film on a surface of a substrate using the film forming composition comprising the Si-precursor and the methods described in any of the above related paragraphs. The substrate processing apparatus comprises at a vapor deposition assembly that comprises at least one reaction chamber comprising a means for housing a substrate within the at least one reaction chamber, an optional supply of the hydrogen source and a means for introducing the optional hydrogen source into the reaction chamber, a supply of the film forming composition comprising the Si-precursor and a means for introducing a vapor of the film forming composition comprising the Si-precursor into the reaction chamber, and a means for generating a plasma within the reaction chamber.

In some embodiments, the plasma is a remote plasma. In some of these embodiments, the plasma is an inductively coupled plasma (ICP).

In some embodiment, the vapor deposition assembly further comprises a controller that is operably connected to an optional hydrogen source supply, a Si-precursor supply, and a plasma generator. The controller may be configured and programed to optionally supply the hydrogen source to the reaction chamber and cease the supply of the hydrogen source to the reaction chamber, to supply the Si-precursor to the reaction chamber and cease the supply of the Si-precursor to the reaction chamber, and to supply the plasma to the reaction chamber and to cease the supply of the plasma to the reaction chamber. In some of these embodiments the supply of the optional hydrogen source, the Si-precursor and the plasma to the reaction chamber overlap, at least in part.

Another aspect of the present disclosure relates to structures that comprise a low-k material film that is formed using the film forming compositions and the methods and systems described in any of the above related paragraphs. The structure may comprise a substrate, a feature, and spacer. The spacer may comprise a low-k material layer that is formed according to methods disclosed in any of the above related paragraphs and then removing a portion of the layer in one or more subsequent processing steps.

These aspects and other embodiments will be readily apparent to those skilled in the art from the following detailed description of certain embodiments and with further reference to the attached figures. These embodiments or components thereof may be combined, or they may be applied separate from each other, as applicable, unless otherwise noted. The invention is not limited to any particular embodiments disclosed.

### BRIEF DESCRIPTION OF DRAWINGS

The accompanying drawings constitute part of the specification. The drawings are included to provide a further understanding of the disclosure, and together with the description explain certain principles of the disclosure. The drawings illustrate exemplary embodiments of how the disclosure can be made and used and are not to be construed as limiting the disclosure to only the illustrated and described examples. It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure. Further features and advantages will become apparent from the following, more detailed, description of various aspects, embodiments, and configurations of the disclosure, as illustrated by the drawings referenced below.

FIG. 1 is an exemplary process flow diagram of a method for forming a low-k material film on a surface of a substrate according to the present disclosure. Optional steps are shown by the features or elements in the dashed lines.

FIGS. 2A-2D show exemplary timing sequences for various process steps for forming a low-k material film on a surface of a substrate. Optional steps are shown by the features or elements in the dashed lines.

FIG. 3 is a schematic presentation of a vapor deposition assembly according to an embodiment of the present disclosure.

FIG. 4 illustrates a structure including a spacer formed in accordance with examples of the disclosure.

### DETAILED DESCRIPTION

The description of embodiments of film forming compositions, methods, systems, and structures provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. Unless otherwise noted, the exemplary embodiments or components thereof may be combined or may be applied separate from each other. The headings provided herein, if any, are for convenience only and do not necessarily affect the scope or meaning of the claimed invention.

As used herein, an “alkenyl group” refers a functional group that comprises a carbon-carbon double bond. An alkenyl group may have a structure according to the formula CxH2x−1, where x is an integer that is typically from 1 to 6. Generally, an alkenyl group is a part of a larger molecule, and the symbol “R” may be used to designate a generic unspecified alkenyl group. In cases where a molecule has more than one R group, each R group may be independently selected. As used herein, an “alkyl group” refers a functional group that can be derived from an alkane (e.g., an alkane less a hydrogen atom). An alkyl group may have a linear or branched structure according to the formula CxH2x+1, or a cyclic structure according to CxH2x−1, where x is an integer that is typically from 1 to 6. Generally, an alkyl group is a part of a larger molecule, and the symbol “R” may be used to designate a generic unspecified alkyl group. In cases where a molecule has more than one R group, each R group may be independently selected. In some embodiments of the present disclosure, an alkyl group refers to a linear or branched C1 to C6 alkane less one hydrogen atom (i.e., a C1 to C6 alkyl group), such as a methyl group (CH3), an ethyl group (CH2CH3), an n-propyl group (CH2CH2CH3), an iso-propyl group (CH(CH3)2), an n-butyl group (CH2CH2CH2CH3), an iso-butyl group (CH2CH(CH3)CH3), a s-butyl group (CH(CH3)CH2CH3), a t-butyl group (C(CH3)3), an n-pentyl group (CH2CH2CH2CH2CH3), a 2-pentyl group (CH(CH3)CH2CH2CH3), a 3-pentyl group (CH2CH(CH3)CH2CH3), a neo-pentyl group (CH2C(CH3)3), a t-pentyl group (C(CH3)2CH2CH3), an iso-pentyl group (CH2CH2CH(CH3)2), a sec-iso-pentyl group (C(CH3)CH(CH3)2) and a hexyl group. In some embodiments, an alkyl group refers a methyl group (CH3) or an ethyl group (CH2CH3).

As used herein, an “alkoxy group” refers a functional group or a substituent that is derived from an organic alcohol minus the alcohol hydrogen. An alkoxy group may have a structure according to the formula OCxH2x+2, where x is an integer typically from 1 to 6. Generally, an alkoxy group is a part of a larger molecule, and the symbol “R” may be used to designate a generic unspecified alkoxy group. In cases where a molecule has more than one R group, each R group may be independently selected. In some places throughout the disclosure an alkoxy group may be expressed as OR′, where R′ is an alkyl group. In some embodiments of the present disclosure, an alkoxy group refers to a linear or branched C1 to C6 alkoxy group, such as a methoxy group (OCH3), an ethoxy group (OCH2CH3), an n-propoxy group (OCH2CH2CH3), an iso-propoxy group (OCH(CH3)2), an n-butoxy group (OCH2CH2CH2CH3), an iso-butoxy group (OCH2CH(CH3)CH3), a s-butoxy group (OCH(CH3)CH2CH3), and a t-butoxy group (OC(CH3)3).

As used herein, “atomic layer deposition”, abbreviated as “ALD”, refers to a vapor deposition process in which deposition cycles, such as a plurality of consecutive deposition cycles, are conducted in one or more reaction chambers. Generally, in ALD processes, during each deposition cycle, a precursor is introduced into a reaction chamber and is adsorbed onto a substrate surface, which may include a previously deposited material from a previous ALD cycle or other materials, forming maximally one monolayer of the precursor that does not readily react with additional excess precursor (i.e., a self-limiting reaction). Thereafter, in some cases, another precursor or a reactant may be introduced into the reaction chamber to convert the adsorbed precursor to the desired material on the substrate surface. Other reaction steps may be included in the deposition cycle. ALD may occur by a thermal process (thermal ALD), where the reaction(s) are promoted by increasing the temperature of the substrate relevant to ambient temperature; or by a plasma enhanced process (PE-ALD) or radical enhanced process (RE-ALD), where the reaction(s) are promoted through the use of energetic plasma species. ALD, as used herein, may also be meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of reactants.

As used herein, “chemical vapor deposition”, abbreviated as “CVD”, refers to a vapor deposition process in which a film is deposited on a substrate by exposing its surface to one or more gaseous precursors and reactants, which react and/or decompose near and/or on the substrate surface to form the film. The precursors and/or reactants can be provided simultaneously to the reaction chamber, or in partially or completely separated pulses. In some embodiments, the precursors and/or reactants are provided until a layer having a desired thickness and/or uniformity is deposited. In some embodiments, a cyclic CVD process can be used with multiple cycles to deposit a thin film having a desired thickness.

As used herein, a “cyclic deposition process” refers to a method or a process comprising sequentially introducing precursors and/or reactants into a reaction chamber to deposit a layer or a film on or over a substrate and includes processing techniques such cyclical CVD.

As used herein, a “film” or “layer”, which may be used interchangeably, refers to a continuous, substantially continuous, or non-continuous material that extends in a direction perpendicular to a thickness direction to cover at least a portion of a surface. A film may be positioned on a lateral surface and/or on a sidewall of recessed features of a surface. A film can include two-dimensional materials, three-dimensional materials, nanoparticles, partial or full molecular layers, partial or full atomic layers, and/or clusters of atoms or molecules. A film may be built up from one or more non-discernable monolayers or sub-monolayers to produce a uniform or a substantially uniform material, wherein the number of monolayers or sub-monolayers influences the thickness of the film.

As used herein, a “gas” refers to a state of mater consisting of atoms or molecules that have neither a defined volume nor shape. A gas includes vaporized solid and/or liquid and may be referred to as a vapor. A gas may be constituted by a single gas or a mixture of gases, depending on the context.

As used herein, a “precursor” refers to a compound that participates in a chemical reaction to form another compound or element, wherein a portion of the precursor (an element or group within the precursor) is incorporated into the compound or element that results from the chemical reaction. The compound or element that results from the chemical reaction may be a layer and/or a film that is formed on a surface of a substrate.

As used herein, the term “purge” refers to a procedure in which vapor phase precursors, reactants, and/or vapor phase byproducts are removed from a substrate surface for example by evacuating the reaction chamber with a vacuum pump and/or by replacing the gas inside a reaction chamber with an inert or substantially inert gas such as argon or nitrogen. Purging may be affected between two pulses of gases which react with each other. Purging may also be affected between two pulses of gases that do not react with each other. For example, a purge or purging may be provided between pulses of two precursors or between a precursor and a reactant. Purging may avoid or at least reduce gas-phase interactions between the two gases reacting with each other. It shall be understood that a purge can be affected either in time or in space, or both. For example, in the case of temporal purges, a purge step can be used, for example, in a temporal sequence of providing a first reactant to a reaction chamber, providing a purge gas to the reaction chamber, and providing a second reactant to the reaction chamber, wherein the substrate on which a layer is deposited does not move. For example, in the case of spatial purges, a purge step can comprise moving a substrate from a first location to which a first reactant is continually supplied, through a purge gas curtain, to a second location to which a second reactant is continually supplied.

As used herein, a “reactant” refers to a compound that participates in a chemical reaction to form another compound or element. In some instances, a reactant is a precursor. In other instances, the compound or element that results from the chemical reaction does not contain a portion, or a significant portion, of the reactant (an element or group within the reactant) and therefore the reactant is not a precursor.

As used herein, “silicon oxycarbide”, abbreviated as “SiOC”, can refer to material that includes silicon, oxygen, and carbon. As used herein, unless stated otherwise, SiOC is not intended to limit, restrict, or define the bonding or chemical state, for example, the oxidation state of any of Si, C, O, and/or any other element in the film. In some embodiments, SiOC may comprise one or more elements in addition to Si, C, and O, such as H or N. In some embodiments, the SiOC may not comprise N. In some embodiments, the SiOC may comprise Si—C bonds and/or Si—O bonds. In some embodiments, the SiOC may comprise Si—H bonds in addition to Si—C and/or Si—O bonds. In some embodiments, the SiOC may comprise greater than 0% to about 60% carbon on an atomic basis. In some embodiments, the SiOC may comprise from about 0.1% to about 50%, from about 0.5% to about 40%, from about 1% to about 30%, or from about 5% to about 20% carbon on an atomic basis. In some embodiments, the SiOC may comprise greater than 0% to about 70% oxygen on an atomic basis. In some embodiments, the SiOC may comprise from about 10% to about 70%, from about 15% to about 50%, or from about 20% to about 40% oxygen on an atomic basis. In some embodiments, the SiOC may comprise greater than 0% to about 50% silicon on an atomic basis. In some embodiments, the SiOC may comprise from about 10% to about 50%, or from about 15% to about 40%, or from about 20% to about 35% silicon on an atomic basis. In some embodiments, the SiOC may further comprise from about 0.1% to about 40%, or from about 0.5% to about 30%, or from about 1% to about 30%, or from about 5% to about 20% hydrogen on an atomic basis.

As used herein, “silicon oxycarbon nitride”, abbreviated as “SiOCN”, can refer to material that includes silicon, oxygen, carbon, and nitrogen. As used herein, unless stated otherwise, SiOCN is not intended to limit, restrict, or define the bonding or chemical state, for example, the oxidation state of any of Si, C, O, N, and/or any other element in the film. In some embodiments, SiOCN may comprise one or more elements in addition to Si, C, O, and N, such as H. In some embodiments, the SiOCN may comprise Si—C bonds and/or Si—O bonds and/or Si—N bonds. In some embodiments, the SiOCN may comprise Si—H bonds in addition to Si—C and/or Si—O bonds and/or Si—N bonds. In some embodiments, the SiOCN may comprise greater than 0% to about 60% carbon on an atomic basis. In some embodiments, the SiOCN may comprise from about 0.1% to about 50%, or from about 0.5% to about 40%, or from about 1% to about 30%, or from about 5% to about 20% carbon on an atomic basis. In some embodiments, the SiOCN may comprise greater than 0% to about 70% oxygen on an atomic basis. In some embodiments, the SiOCN may comprise from about 10% to about 70%, or from about 15% to about 50%, or from about 20% to about 40% oxygen on an atomic basis. In some embodiments, the SiOCN may comprise greater than 0% to about 20% nitrogen on an atomic basis. In some embodiments, the SiOCN may comprise from about 0.1% to about 20%, or from about 0.5% to about 15%, or from about 1% to about 10%, or from about 1.5% to about 5% nitrogen on an atomic basis. In some embodiments, the SiOCN may comprise greater than 0% to about 50% silicon on an atomic basis. In some embodiments, the SiOCN may comprise from about 10% to about 50%, or from about 15% to about 40%, or from about 20% to about 35% silicon on an atomic basis. In some embodiments, the SiOCN may further comprise from about 0.1% to about 40%, or from about 0.5% to about 30%, or from about 1% to about 30%, or from about 5% to about 20% hydrogen on an atomic basis.

As used herein, a “substrate” refers to an underlying material or materials that may be used to form, or upon which, a device, a circuit, a material, or a material layer may be formed. The substrate may be continuous or non-continuous; rigid or flexible; solid or porous; and combinations thereof. The substrate may be in any form, such as, for example, a powder, a sheet, a plate, or a workpiece. Substrates in the form a sheet may extend beyond the bounds of a process/reaction chamber where a deposition process occurs and, in some cases, move through the chamber such that the process continues until the end of the substrate is reached. Substrates in the form of a plate may include wafers in various shapes and sizes. Substrates may be made from semiconductor materials, including, for example, silicon, silicon germanium, silicon oxide, gallium arsenide, gallium nitride, and silicon carbide. A substrate can include one or more layers overlying a bulk material, for example the substrate may include nitrides, for example TiN, oxides, insulating materials, dielectric materials, conductive materials, metals, such as tungsten, ruthenium, molybdenum, cobalt, aluminum, or copper, or other metallic materials, crystalline materials, epitaxial, heteroepitaxial, and/or single crystal materials. The substrate can include various topologies, such as, for example, gaps, recesses, lines, trenches, vias, holes, or spaces between elevated portions, such as fins, and the like formed within or on at least a portion of a layer of the substrate. Although the term substrate may be used in singular form throughout the disclosure, it should be understood that the term substrate can include one or more substrates unless explicitly stated otherwise.

As used herein, a “wet etch rate”, abbreviated as “WER”, refers to the rate of material loss when said material is exposed to a liquid etchant. For example, the WER may refer to the loss of material from a layer, which may be determined by measuring the decrease in a thickness of the layer as a function of time. In some embodiments, the WER may be measured by exposing the layer to dilute hydrofluoric acid, for example 1% dilute hydrofluoric acid.

Articles “a” or “an” refer to a species or a genus including multiple species, depending on the context. As such, the terms “a/an”, “one or more”, and “at least one” can be used interchangeably herein.

The terms “comprising”, “including”, and “having” are open ended and do not exclude the presence of other elements or components, unless the context clearly indicates otherwise. Comprising, including, and having can be used interchangeably and include the meaning of “consisting of”. The phrase “consisting of”, however, indicates that no other features or components are present other than those mentioned, unless the context clearly indicates otherwise. The term “about” as applied to a value generally refers to a range of numbers that is considered to be equivalent to the recited value (e.g., having the same function or result). In some instances, the term “about” may include numbers that are rounded to the nearest significant figure.

The term “essentially” as applied to a film forming composition, a method, a system, or a structure generally means that the additional components do not substantially modify the properties, characteristics, and/or function of the film forming composition, the method, the system, or the structure.

The term “substantially” as applied to a film forming composition, a method, a system, or a structure generally refers to a proportion of a value, a property, a characteristic, or the like, or conversely a lack thereof, that is at least about 70%, or at least about 80%, or at least about 90%, or at least about 95%, or at least about 97%, or at least about 98%, or at least about 99%, or at least about 99.5%, or at least about 99.9%, or more, or any proportion between about 70% and about 100%. In some embodiments, the term “substantially” means a proportion of about 90%, or about 95%, or about 97%, or about 98%, or about 99%, or about 99.5%, or about 99.9%.

The terms “on” or “over” may be used to describe a relative location relationship. For example, an element, a film, or a layer may be directly positioned on or over and physically contacting at least a portion another element, film, or layer; or, alternatively, an element, a film, or a layer may be on or over another element, film or layer but have one or more interposed elements, films, or layers therebetween. Therefore, unless the term “directly” is separately used, the terms “on” or “over” will be construed to be a relative concept. Similar to this, it will be understood that the terms “under”, “underlying”, or “below” describe a relative location relationship and should be construed to be relative concepts.

The terms “at least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C”, and “A, B, and/or C” means A alone, B alone, C alone, A and B together, A and C together, B and C together, or A, B, and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Z1).

It should be understood that every numerical range given throughout this disclosure is deemed to include the upper and the lower end points, and each and every narrower numerical range that falls within such broader numerical range, as if such narrower numerical ranges were all expressly written herein. By way of example, the phrase “from about 2 to about 4” or “from 2 to 4” includes 2 and 4 and the whole number and/or integer ranges from about 2 to about 3, from about 3 to about 4, and each possible range based on real (e.g., irrational and/or rational) numbers, such as from about 2.1 to about 3.9, from about 2.1 to about 3.4, and so on.

The standard abbreviations of the elements in the periodic table are used herein.

In certain places throughout the disclosure, a chemical compound, a functional group of a chemical compound, or a substituent or ligand may be referred to by a chemical name (e.g., an IUPAC name or a common name), a chemical formula which may be abbreviated, or both. In cases where there is a conflict between the chemical name and/or the chemical formula, and the identity of the chemical compound, the functional group, or the substituent or ligand cannot be unambiguously ascertained by one of skill in the art, then the chemical formula shall prevail.

In this disclosure, any defined meanings do not necessarily exclude ordinary and customary meanings, in some embodiments.

Disclosed herein are film forming compositions and methods and systems for using said compositions to deposit a low-k material film on a surface of a substrate using a plasma enhanced vapor deposition process. The film forming compositions comprise a Si-precursor that comprises at least one silicon atom that is bonded to an oxygen atom and to an optionally substituted vinyl group. As will be elaborated on below, the structure of the Si-precursor may advantageously impact the quality of the resulting low-k material film. The disclosed compositions, methods, and systems may be useful for low-k spacer applications in advanced semiconductor devices, such as, for example, as gate spacers in logic devices or bit line spacers in memory devices.

Various aspects of the disclosure relate to the formation of a low-k material film and also to structures comprising the low-k material film. In these aspects, the low-k material film comprises silicon (Si), oxygen (O), and carbon (C). In some embodiments, the low-k material film further comprises nitrogen (N). In some embodiments, the low-k material film further comprises hydrogen (H). In some embodiments, the low-k material film comprises silicon oxycarbide (SiOC). In some embodiments, the low-k material film consists or consists essentially of SiOC. In some embodiments, the low-k material film comprises silicon oxycarbon nitride (SiOCN). In some embodiments, the low-k material film consists of or consists essentially of SiOCN.

An aspect of the present disclosure relates to film forming compositions that are configured to deposit a low-k material film. The film forming compositions comprise a Si-precursor that comprises at least one silicon atom that is bonded to an oxygen atom and to an optionally substituted vinyl group. The optionally substituted vinyl group may be vinyl (—CH═CH2) or a vinyl group that is substituted with one or more C1-C4 alkyl groups, typically one or more methyl groups (CH3). The at least one silicon atom may further be bonded to one of a hydrogen (H) atom, a C1-C6 alkyl group, and a second optionally substituted vinyl group. Examples of C1-C6 alkyl group(s) include, but are not limited to, methyl (CH3), ethyl (C2H5), iso-propyl (iso-C3H7), n-propyl (n-C3H7), t-butyl (t-C4H9), sec-butyl (t-C4H9), iso-butyl (iso-C4H9), n-butyl (n-C4H9), n-pentyl (n-C5H11), iso-pentyl (iso-C5H11), neo-pentyl (neo-C5H11), sec-pentyl (sec-C5H11), isobutyl, isoamyl-pentyl (C5H11), tert-pentyl (t-C5H11), and so forth. In some embodiments, the alkyl group is a methyl group or an ethyl group.

In some embodiments, the film forming composition comprises a silicon precursor that has a silicon atom that is bonded to an oxygen atom and to an optionally substituted vinyl group. In some of these embodiments, the Si-precursor has a structure according to general formula (1):

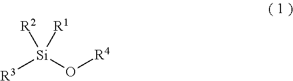

wherein R1 is the optionally substituted vinyl group; R2 is selected from the group consisting of an H atom, a C1-C6 alkyl group, and a second optionally substituted vinyl group; R3 is selected from the group consisting of an H atom and a C1-C6 alkyl group; and R4 is selected from the group consisting of a C1-C6 alkyl group and a C2-C6 alkenyl group. In some of these embodiments, one of both of R2 and R3 is an H atom.

In some of these embodiments, the Si-precursor has a structure according to general formula (1), wherein R1 is the optionally substituted vinyl group; R2 is selected from the group consisting of an H atom and a C1-C6 alkyl group; R3 is selected from the group consisting of an H atom and a C1-C6 alkyl group; and R4 is a C1-C6 alkyl group. In some of these embodiments, one of both of R2 and R3 is an H atom.

In some of these embodiments, the Si-precursor has a structure according to general formula (1), wherein R1 is the optionally substituted vinyl group; R2 is selected from the group consisting of an H atom and a C1-C6 alkyl group; R3 is an H atom; and R4 is a C1-C6 alkyl group. In some of these embodiments, one of both of R2 is an H atom.

In some of these embodiments, the Si-precursor is selected from the group consisting of ethenylmethoxysilane, ethenylethoxysilane, ethenylmethoxymethylsilane, ethenylethoxymethylsilane, ethenylethoxyethylsilane, ethenylethoxydimethylsilane, ethenylethoxydiethylsilane, diethenylmethoxysilane, diethenylethoxysilane, diethenylmethoxymethylsilane, and diethenylethoxymethylsilane.

In other embodiments, the film forming composition comprises a Si-precursor that has two or more silicon atoms that are each bonded to an oxygen atom and to an optionally substituted vinyl group. In some of these embodiments, the Si-precursor has a cyclic structure according to general formula (2):

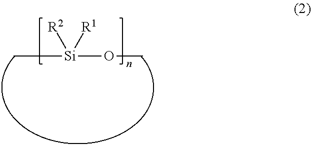

wherein n is an integer selected from 2, 3, 4, or 5; each R1 is independently the optionally substituted vinyl group; and each R2 is independently selected from the group consisting of an H atom, a C1-C6 alkyl group, and a second optionally substituted vinyl group. In certain embodiments, each R1 is the optionally substituted vinyl group; and each R2 is a C1-C6 alkyl group, typically R2 is a methyl group or an ethyl group.

In some of these embodiments, the Si-precursor having a structure according to general formula (2) has a four membered ring structure (i.e., n=2), generally shown in formula (2a):

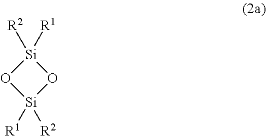

wherein R1 is the optionally substituted vinyl group; and R2 is selected from the group consisting of an H atom, a C1-C6 alkyl group, and a second optionally substituted vinyl group. In some of these embodiments, the Si-precursors is selected from the group consisting of 1,3-divinylcyclodisiloxane, 1,3-dimethyl-1,3-divinylcyclodisiloxane, 1,3-diethyl-1,3-divinylcyclodisiloxane, and 1,1,3,3-tetravinylcyclodisiloxane.

In some of these embodiments, the Si-precursor having a structure according to general formula (2) has a six membered ring structure (i.e., n=3), generally shown in formula (2b):

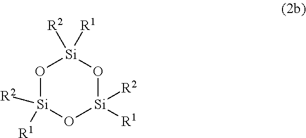

wherein each R1 is independently the optionally substituted vinyl group; and each R2 is independently selected from the group consisting of an H atom, a C1-C6 alkyl group, and a second optionally substituted vinyl group. In some of these embodiments, the Si-precursors is selected from the group consisting of 1,3,5-trivinylcyclotrisiloxane, 1,3,5-trimethyl-1,3,5-trivinylcyclotrisiloxane, 1,3,5-triethyl-1,3,5-trivinylcyclotrisiloxane, and 1,1,3,3,5,5-hexavinylcyclotrisiloxane.

In some of these embodiments, the Si-precursor having a structure according to general formula (2) has an eight membered ring structure (i.e., n=4), generally shown in formula (2c):

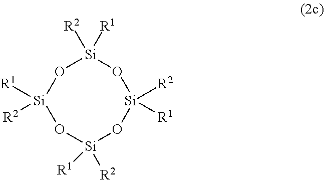

wherein each R1 is independently the optionally substituted vinyl group; and each R2 is independently selected from the group consisting of an H atom, a C1-C6 alkyl group, and a second optionally substituted vinyl group. In some of these embodiments, the Si-precursors is selected from the group consisting of 1,3,5,7-tetravinylcyclotetrasiloxane, 1,3,5,7-tetramethyl-1,3,5,7-tetravinylcyclotetrasiloxane, 1,3,5,7-tetraethyl-1,3,5,7-tetravinylcyclotetrasiloxane, and 1,1,3,3,5,5,7,7-octavinylcyclotetrasiloxane.

In some of these embodiments, the Si-precursor having a structure according to general formula (2) has a ten membered ring structure (i.e., n=5), generally shown in formula (2d):

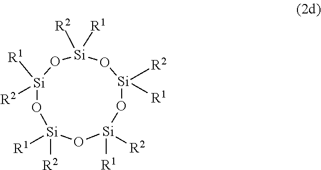

wherein each R1 is independently the optionally substituted vinyl group; and each R2 is independently selected from the group consisting of an H atom, a C1-C6 alkyl group, and a second optionally substituted vinyl group. In some of these embodiments, the Si-precursors is selected from the group consisting of 1,3,5,7,9-pentavinylcyclopentasiloxane, 1,3,5,7,9-pentamethyl-1,3,5,7,9-pentavinylcyclopentasiloxane, 1,3,5,7,9-pentaethyl-1,3,5,7,9-pentavinylcyclopentasiloxane, and 1,1,3,3,5,5,7,7,9,9-decavinylcyclopentasiloxane.

In some embodiments, the Si-precursor is the main component of the film forming composition. For example, the film forming composition may comprises the Si-precursor and one or more impurities, stabilizer(s), and/or solvent(s). In some embodiments, the film forming composition has a purity of 95 wt. % or more (based on the weight of the Si-precursor). In some embodiments, the film forming composition has a purity of about 95 wt. % or more, or about 97 wt. % or more, about 98 wt. % or more, about 99 wt. % or more, about 99.5 wt. % or more, about 99.9 wt. % or more, about 99.99 wt. % or more, or about 99.999 wt. % or more, or even about 99.9999 wt. % (based on the weight of the Si-precursor).

In some embodiments, the film forming composition comprising the Si-precursor is provided in a precursor delivery vessel. The precursor delivery vessel is configured to store the film forming composition and to provide a flow of the film forming composition from the precursor delivery vessel to an external environment, for example, to a substrate processing apparatus for forming a low-k material film on a surface of a substrate. In some embodiments, the precursor delivery vessel is a liquid delivery vessel; hence the vessel is configured to deliver a liquid flow of the film forming composition from the vessel to an external environment for vaporization. In other embodiments, the precursor delivery vessel is a vapor delivery vessel; hence the vessel is configured to deliver a vapor flow of the film forming composition from the vessel to an external environment. The configuration of the precursor delivery vessel may vary in different embodiments of the disclosure, depending upon the application in question. However, the precursor delivery vessel is generally formed from a material that is non-reactive to the film forming composition and, in some embodiments, may also be compliant with U.S. Department of Transportation (DOT) regulation, such as 49 C.F.R. § 178 (2021). In some embodiments, the precursor delivery vessel is formed from stainless steel (e.g., 316, 316L, 304, or 304L alloys). The precursor delivery vessel generally comprises an outer wall that encloses a cavity for storing the film forming composition and an outlet for allowing a flow of the film forming composition to exit the cavity. The outlet is seated in the outer wall of the precursor delivery vessel and is in communication with the cavity of the precursor delivery vessel and has at least one valve positioned thereon to fluidly couple or decouple the cavity to the outside environment.

In some embodiments, the precursor delivery vessel comprises one or more other fluid inlets or outlets, in addition to the outlet. For example, the precursor delivery vessel may comprise a fluid inlet that is seated in the outer wall of the precursor delivery vessel and is in communication with the cavity of the precursor delivery vessel and having at least one valve positioned thereon for filling the precursor delivery vessel with the film forming composition. Additionally, or alternatively, the precursor delivery vessel may comprise a fluid inlet that is seated in the outer wall of the precursor delivery vessel and is in communication with the cavity of the precursor delivery vessel and having at least one valve positioned thereon for flowing a carrier gas into the cavity of the vessel, either over the surface of the film forming composition and/or through the film forming composition in the case of vapor delivery, or for pressurizing the cavity of the vessel in the case of liquid delivery to help facilitate the flow of the film forming composition from the precursor delivery vessel. Some or all of the one or more valves provided on the various inlets and outlets may be rated for high temperature (e.g., typically up to 100° C., or up to 150° C., or up to 200° C., or up to 250° C.) to withstand the temperatures that may be required to provide sufficient vapor pressure and/or prevent condensation of the film forming composition within the values and other components, and/or to obtain a sufficient viscosity to facilitate flow from the precursor delivery vessel.

In some embodiments, the precursor delivery vessel further comprises one or more probe members, that may comprise one or more temperature sensors, and/or one or more pressure sensors, and/or one or more level sensors. A variety of level sensors for measuring the amount of the film forming composition within the cavity of the precursor delivery vessel are known in the art, including, but not limited to, capacitive-based sensors, conductivity-based sensors, float switch level sensors, tuning fork sensors, and ultrasonic sensors. The various design features described above may be combined, as appropriate, to optimize the flow of the film forming composition from the precursor delivery vessel.

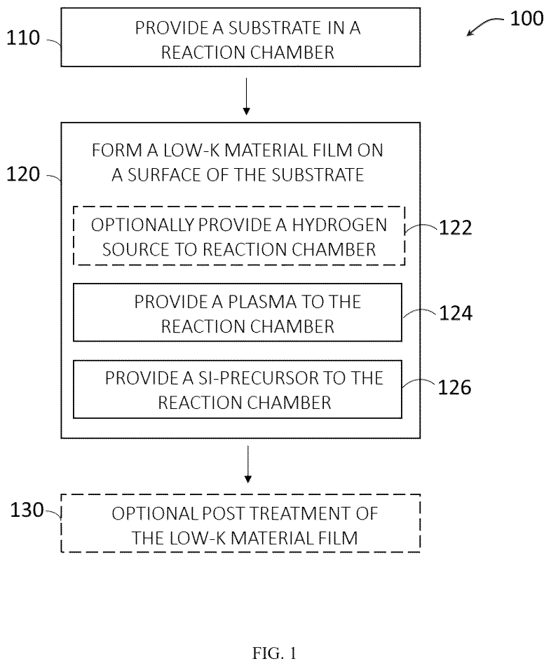

Another aspect of the present disclosure relates to methods of forming a low-k material film on a surface of a substrate using a vapor deposition process. Suitable vapor deposition processes include plasma-enhanced chemical vapor deposition (PE-CVD), which may include continuous and cyclic CVD methods, and plasma-enhanced atomic layer deposition (PE-ALD). FIG. 1 is a process flow diagram of a vapor deposition method 100 for forming the low-k material film on a surface of a substrate in accordance with exemplary embodiments of the disclosure. The method generally comprises providing a substrate in a reaction chamber 110 and forming a low-k material film on the surface of the substrate 120 by optionally providing a hydrogen source to the reaction chamber 122, providing a plasma to the reaction chamber 124, and providing a Si-precursor to the reaction chamber 126. The various steps for forming the low-k material film can be performed continuously, sequentially, or some combination thereof. The method may optionally comprise post treating the low-k material film 130.

In the disclosed methods, a substrate is provided in a reaction chamber 110 where the deposition conditions can be controlled. The substrate is not particularly limited and is discussed above. The reaction chamber may be a component of a vapor deposition assembly, which in turn maybe a component of a substrate processing apparatus. The reaction chamber may one of a multitude of chambers in a cluster tool in which different processes are performed in the various chambers to form components of an integrated circuit.

The step of providing the substrate in the reaction chamber 110 may further comprises maintaining a temperature of the substrate and/or a temperature of the reaction chamber at a set temperature. For instance, the substrate may be maintained at an elevated temperature (i.e., above room temperature). In some embodiments, the substrate may be maintained at a first temperature during the deposition process and a second temperature during other process steps. The temperature of the substrate may be optimized to tune or maximize the deposition process on the substrate surface. In some embodiments, the method further comprises heating the substrate to a temperature of at least about 40° C. to no more than about 500° C. In some embodiments, the method comprises maintaining the substrate temperature from about 50° C. to about 500° C., typically from about 100° C. to about 450° C., or from about 100° C. to about 400° C., or from about 100° C. to about 350° C., or from about 100° C. to about 325° C., or from about 100° C. to about 300° C., or from about 100° C. to about 275° C., or from about 100° C. to about 250° C., or from about 100° C. to about 200° C. In some embodiments, the method further comprises heating the substrate to a temperature of less than about 450° C., or less than about 425° C., or less than about 400° C., or less than about 375° C., or less than about 350° C., or less than about 325° C., or less than about 300° C., or less than about 275° C., or less than about 250° C., or less than about 200° C.

The step of providing the substrate in the reaction chamber 110 may further comprises controlling a pressure within the reaction chamber. In some embodiments, the reaction chamber may be maintained at a first pressure during a first deposition process and a second pressure during other process steps. The pressure within the reaction chamber may be between about 1 mTorr and about 760 Torr, typically between about 0.5 Torr and about 100 Torr, such as about 5 Torr, or about 10 Torr, or about 15 Torr, or about 20 Torr, or about 30 Torr, or about 40 Torr, or about 50 Torr, or about 10 Torr, or about 5 Torr. In some embodiments, a pressure within the reaction chamber during the cyclic deposition process is less than about 100 Torr, or a pressure within the reaction chamber during the cyclic deposition process is between about 0.5 Torr and about 100 Torr, or between about 1 Torr and about 50 Torr, or between about 1 Torr and about 20 Torr, or between about 1 Torr and about 10 Torr, or between about 2 Torr and about 5 Torr.

In some embodiments, the step of providing the substrate in the reaction chamber 110 further comprises providing a seal gas to the reaction chamber. The seal gas is generally an inert gas (e.g., He, Ar, or N2) that is provided to one or more transfer regions of the reaction chamber to mitigate flow of other gasses to and/or from the transfer region(s) to the deposition region of the reaction chamber. The flow rate of the seal gas into the reaction chamber may be less than about 5000 sccm, or less than about 4000 sccm, or less than about 3000 sccm, or less than about 2000 sccm, or less than about 1000 sccm, or less than about 500 sccm, or less than about 400 sccm, or less than about 300 sccm, or less than about 200 sccm, or less than about 100 sccm.

In the disclosed methods, a low-k material film is formed on a surface of the substrate 120 by optionally providing a hydrogen source to the reaction chamber 122, providing a plasma to the reaction chamber 124, and providing a Si-precursor to the reaction chamber 126. The order of the various steps and the timing and duration of the individual steps can vary in different embodiments of the disclosure. The deposition method may be a continuous deposition process or it may be a cyclic deposition process. In some embodiments, one or more of the process steps may be performed continuously. The term “continuously” may refer to one or more of without breaking a vacuum, without temporal interruption, without spatial interruption, and without any material intervening step. For example, one or more of the hydrogen source, the Si-precursor, and the plasma can be supplied continuously during two or more steps, during a deposition cycle, and/or during two or more deposition cycles of a method. In some embodiments, one or more of the process steps may overlap, at least in part, with one or more other process steps. In other embodiments, one or more of the process steps may be separate from one or more other process steps. The terms “overlap” and “separate” refer the overlap or separation of the process steps temporally and/or spatially.

The Si-precursor is provided to the reaction chamber 126. The Si-precursor is provided in a film forming composition that comprises the Si-precursor. The film forming composition comprises a Si-precursor that comprises at least one silicon atom that is bonded to an oxygen atom and to an optionally substituted vinyl group. The optionally substituted vinyl group may be vinyl (CH═CH2) or a vinyl group that is substituted with one or more C1-C4 alkyl groups, typically one or more methyl groups (CH3). The at least one silicon atom may further be bonded to one of a hydrogen atom, a C1-C6 alkyl group, and a second optionally substituted vinyl group. The Si-precursor may have a structure according to general formula (1) or general formula (2). The film forming composition and the Si-precursor are discussed in more details in the above text.

The step of providing the Si-precursor to the reaction chamber 126 generally comprises flowing the film forming composition comprising the Si-precursor into the reaction chamber from a precursor delivery vessel that is fluidly coupled to the reaction chamber. The film forming composition comprising the Si-precursor may be provided in liquid form from the precursor delivery vessel and vaporized upstream of the reaction chamber (e.g., using a vaporizer) so that a vapor flow of the film forming composition is introduced into the reaction chamber. Alternatively, the film forming composition may be provided in a vapor form from the precursor delivery vessel and introduced into the reaction chamber. In either case, the film forming composition may optionally be entrained in a flow of at carrier gas or a dilution gas (e.g., a noble gas such as helium (He) and argon (Ar)) and introduced into the reaction chamber. In some embodiments, the Si-precursor is continuously provided to the reaction chamber. In other embodiments, the Si-precursor is pulsed into the reaction chamber. The flow rate of the Si-precursor into the reaction chamber may be less than about 5000 sccm, or less than about 4000 sccm, or less than about 3000 sccm, or less than about 2000 sccm, or less than about 1000 sccm, or less than about 500 sccm, or less than about 400 sccm, or less than about 300 sccm, or less than about 200 sccm, or less than about 100 sccm, or less than about 50 sccm. The flow rate may be, for example, from about 50 sccm to about 2000 sccm, such as about 100 sccm to about 2000 sccm, or about 100 sccm to about 1500 sccm, or about 100 sccm to about 1000 sccm, or about 100 sccm to about 500 sccm. In embodiments where the Si-precursor is pulsed into the reaction chamber, the pulse time may be between about 0.01 second and about 60 seconds, or from about 0.1 second to about 30 seconds, or from about 1 second to about 10 seconds. The flow rate and the pulse time for the Si-precursor may vary in different embodiments of the disclosure according to the specific Si-precursor utilized, the configuration of the reaction chamber, and other process parameters (e.g., temperature, pressure, substrate, plasma conditions, etc.), which may independently be selected to optimize the deposition according to the application in question.

The step of providing a plasma to the reaction chamber 124 generally comprises applying power to a plasma generator to generate an electric or magnetic field to ionize a gas either within the reaction chamber or upstream of the reaction chamber. Plasma generation schemes and geometries, include, but are not limited to, capacitively coupled plasmas (CCPs), inductively coupled plasmas (ICPs), and RF-hollow cathode (HC) plasmas, which differ in their production of excited and reactive species and, as a result, they can provide very different fluxes of the various species. In some embodiments, the plasma is a remote plasma. Use of a remote plasma may be beneficial due to spatial separation of the plasma from the substrate. Such a configuration allows for the delivery of radical and other neutral reactive species to the substrate surface while limiting the flux of ions, a potential source of film damage, to the substrate surface. Further, use of a remote plasma may preserve the structure of the Si-precursor so that certain structural elements of the Si-precursor are retained in the low-k material film. In some embodiments, the plasma is an inductively coupled plasma (ICP). An ICP is beneficial due to the production of high radical densities. Other plasma generation schemes and geometries are possible.

The power for generating the plasma can be varied in different embodiments of the disclosure. In some embodiments, the power for generating the plasma is maintained at about 6000 W or less, typically at least about 10 W and no more than about 6000 W, or at least about 20 W and no more than about 5000 W, or at least about 20 W and no more than about 4000 W, or at least about 20 W and no more than about 3000 W, or at least about 20 W and no more than about 2000 W, or at least about 20 W and no more than about 1000 W. In some embodiments, the power may have a frequency of less than 100 MHz, typically at least about 400 kHz to no more than 100 MHz. The power may, in some embodiments, have a frequency of 400 kHz, 430 kHz, 3 MHz, 13.56 MHz, 27 MHz, and 60 MHz. In some embodiments, a combination of a high frequency power and a low-frequency power is utilized. The low-frequency power may be from 1% to 50% of the high-frequency power, including 1%, 5%, 10%, 15%, 20%, 30%, 40%, and any range of values between any two numbers of the foregoing. The low-frequency power may have a frequency of 400 kHz to 2 MHz, such as 400 kHz or 430 kHz. The high-frequency power may have a frequency of 3 MHz to 100 MHz such as 3 MHz, or 13.56 MHz, or 27 MHz, or 60 MHz; in some embodiments the frequency is 20 MHz or higher. In some embodiments, the total power may be 1000 W or higher, such as 1000 W, or 2000 W, or 3000 W, or 4000 W, or 5000 W, or 6000 W, or 7000 W, and any range of values between any two numbers of the foregoing. In embodiments where an ICP is employed, the power may range from about 1000 W to about 6000 W.

In some embodiments, the plasma is continuously provided to the reaction chamber. In other embodiments, the plasma is pulsed in the reaction chamber. In embodiments where the plasma is pulsed in the reaction chamber, the duration of the plasma power period can be between 0.01 and 60 seconds or from about 0.1 second to about 30 seconds, or from about 1 second to about 10 seconds. The duration of the plasma power period may vary according to the Si-precursor in question, the feed gas composition, the configuration of the reaction chamber, and other process parameters (e.g., temperature, pressure, substrate, etc.), which may independently be selected to optimize the deposition according to the application in question.

Generally, the plasma is generated from a feed gas. The flow rate of the feed gas into the reaction chamber may be less than about 5000 sccm, or less than about 4000 sccm, or less than about 3000 sccm, or less than about 2000 sccm, or less than about 1000 sccm, or less than about 500 sccm, or less than about 400 sccm, or less than about 300 sccm, or less than about 200 sccm, or less than about 100 sccm. In some embodiments, the feed gas comprises an inert gas, such as a noble gas. The noble gas may be selected from a group consisting of helium (He), neon (Ne), argon (Ar), krypton (Kr), xenon (Xe), and mixtures thereof. In some embodiments, the feed gas comprises a reactive gas, such as the hydrogen source. In other words, the hydrogen source is provided with the feed gas, or is the feed gas, to the plasma unit. In some embodiments the feed gas comprises a mixture of a noble gas and the hydrogen source. In some embodiments, the feed gas may further comprise a nitrogen source and/or an oxygen source. In other embodiments, the feed gas is free or essentially free of an oxygen source and/or a nitrogen source; hence the plasma is free or essentially free of oxygen plasma species and/or nitrogen plasma species. The plasma species formed from feed gas may help to excite and/or partially breakdown the Si-precursor, either in the gas phase above the substrate and/or on the surface of the substrate. Additionally, or alternatively, the plasma species formed from the feed gas may react with the Si-precursor and/or fragments of the Si-precursor in the gas phase above the substrate and/or on the surface of the substrate. In particular, hydrogen plasma species (e.g., hydrogen radicals) may react with the optionally substituted vinyl group of the Si-precursor which may facilitate or promote crosslinking of the resulting low-k material film. The presence of hydrogen plasma species may increase the degree of crosslinking in the low-k material film, compared to low-k material films produced with other plasma conditions that are free of or essentially free of hydrogen plasma species. Further, the use of a remote plasma such as an ICP provide a rich source of hydrogen radicals, without the presence of ions which may be problematic for film formation.

In embodiments where a hydrogen source is provided, the step of providing the hydrogen source to the reaction chamber 122 generally comprises flowing the hydrogen source into the reaction chamber from a hydrogen source supply container. The flow rate of the hydrogen source into the reaction chamber may be less than about 5000 sccm, or less than about 4000 sccm, or less than about 3000 sccm, or less than about 2000 sccm, or less than about 1000 sccm, or less than about 500 sccm, or less than about 400 sccm, or less than about 300 sccm, or less than about 200 sccm, or less than about 100 sccm, or less than about 50 sccm. In some embodiments, the hydrogen source is or is a component of the feed gas for plasma generation. In some embodiments, the hydrogen source is continuously provided to the reaction chamber. In other embodiments, the hydrogen source is pulsed into the reaction chamber. The introduction of the hydrogen source 122 overlaps, at least in part, with the step of forming the plasma in the reaction chamber 124.

In some embodiments, the hydrogen source comprises hydrogen (H2) gas or a mixture of hydrogen gas and an inert gas. The hydrogen source may comprise H2 and a noble gas (e.g., He, Ar, Ne, Kr, and Xe), where the H2 and noble gas are provided at a flow ratio from about 20:1 to about 1:20, or from about 10:1 to about 1:10, or from about 5:1 to about 1:5, or from about 1:2 to about 2:1, or about 1:1. In some embodiments, the hydrogen source consists or consists essentially of H2 gas or a mixture of H2 and an inert gas. The hydrogen source may consist or consist essentially of H2 and a noble gas (e.g., He, Ar, Ne, Kr, and Xe), where the H2 and noble gas are provided at a flow ratio from about 20:1 to about 1:20, or from about 10:1 to about 1:10, or from about 5:1 to about 1:5, or from about 1:2 to about 2:1, or about 1:1.

In some embodiments, the hydrogen source comprises a N—H bond containing reactant, either in addition to H2 or as an alternative to H2. In some embodiments, the hydrogen source comprises one or more of ammonia (NH3), hydrazine (N₂H2), a substituted hydrazine, and a mixture of hydrogen and nitrogen (H2/N2). In some embodiments, the hydrogen source consists or consist essentially of one or more of ammonia (NH3), hydrazine (N₂H2), a substituted hydrazine, and a mixture of hydrogen and nitrogen (H2/N2). Use of an N—H bond containing reactant can lead to a nitrogen content of the low-k material film.

In some embodiments, the hydrogen source comprises a Si—H bond containing reactant, either in addition to H2 or as an alternative to H2. In some embodiments, the hydrogen source comprises one or more of a silane, a halosilane, a silanol, and an alkoxysilane. In some embodiments, the hydrogen source comprises a structure according to SixHy, where x is an integer, typically greater than or equal to 1 and less than or equal to 8, preferably greater than or equal to 1 and less than or equal to 4; and y is equal to 2x+2. Suitable silanes include, but are not limited to, silane (SiH4), disilane (Si2H6), trisilane (Si3H8), and tetrasilane (Si4H10). In other embodiments, the hydrogen source comprises a structure according to SixHy(OR′)z, where x is an integer that is greater than or equal to 1 and less than or equal to 8, preferably greater than or equal to 1 and less than or equal to 4; y and z are integers that are greater than or equal to 1 and less than or equal to 2x+1 and where y+z equal to 2x+2; and R′ is independently a H atom or an alkyl group, typically a C1-C4 alkyl group. Use of such structures as the hydrogen source may beneficially increase the oxygen content of the low-k material film, without damaging the underlying substrate.

In other embodiments, a hydrogen source is not provided to the reaction chamber. Use of the hydrogen source may depend upon the specific selection of the Si-precursor. For example, in certain embodiments, the Si-precursor may comprise one or more Si—H bonds which may provide a sufficient source of hydrogen radicals to react to form the low-k material film.

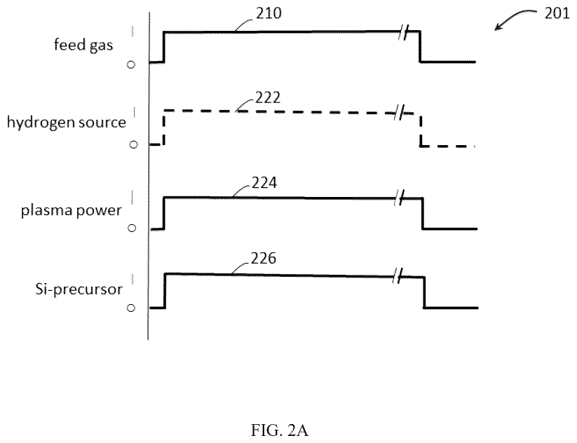

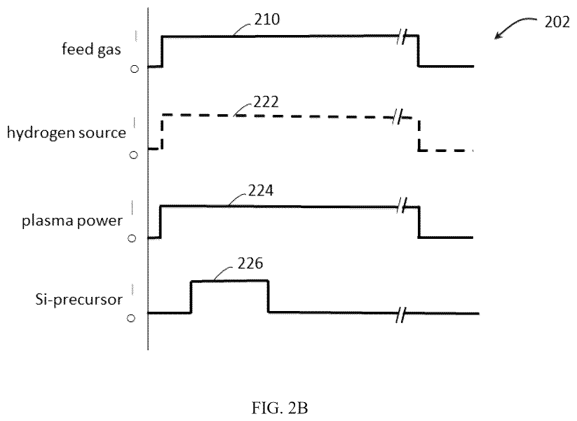

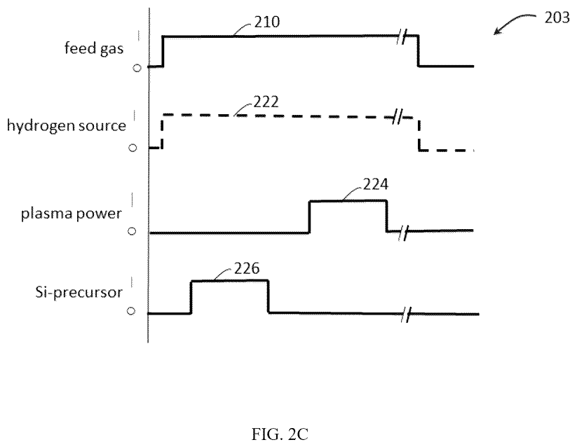

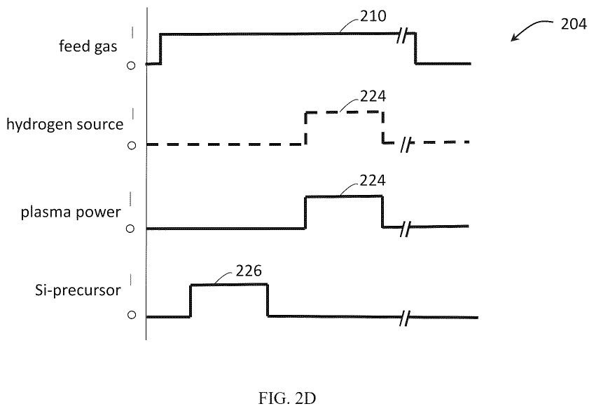

FIGS. 2A-2D shows exemplary timing sequence for the various process steps for forming the low-k material film 120. FIG. 2A shows a continuous deposition process 201 conducted under CVD conditions. A feed gas 210 (discussed below), the optional hydrogen source 222, the plasma formed by applying a plasma power 224, and the Si-precursor 226 are continuously provided to the reaction chamber. The steps of optionally providing the hydrogen source 222, applying the plasma power 224, and providing the Si-precursor 226 to the reaction chamber overlap. FIG. 2B shows one cycle of an exemplary cyclic deposition process 202. The feed gas 210, the optional hydrogen source 222, and the plasma power formed by applying a plasma power 224 are continuously provided to the reaction chamber, while the Si-precursor 226 is pulsed into the reaction chamber. The Si-precursor pulse 226 overlaps with the step of applying the plasma power 224. The Si-precursor pulse 226 may be repeated one or more times in a cyclic deposition process to increase the uniformity and/or thickness of the low-k material film. FIG. 2C shows one cycle of another exemplary cyclic deposition process 203. The feed gas 210 and the optional hydrogen source 222 are continuously provided to the reaction chamber. The Si-precursor 226 and the plasma formed by applying a plasma power 224 are sequentially pulsed into the reaction chamber. The Si-precursor pulse 226 is separate from the plasma pulse 224. The Si-precursor pulse 226 and the plasma pulse 224 may be sequentially repeated one or more times in a cyclic deposition process to increase the uniformity and/or thickness of the low-k material film. FIG. 2D shows one cycle of yet another exemplary cyclic deposition process 204. The feed gas 210 is continuously provided to the reaction chamber. The Si-precursor 226, the optional hydrogen source 222, and the plasma formed by applying a plasma power 224 are sequentially pulsed into the reaction chamber. The Si-precursor pulse 226 is separate from, the optional hydrogen source 222, and the plasma power 224 pulses. The Si-precursor pulse 226, the optional hydrogen source 222, and the plasma power 224 pulses may be sequentially repeated one or more times in a cyclic deposition process to increase the uniformity and/or thickness of the low-k material film.

The timing sequences shown in FIGS. 2A-2D are for illustration purposes and some of the sequences may be simplified. For example, while not explicitly shown, it will be understood that a feed gas supply is required to provide a plasma to the reaction chamber. Thus, in practice, the feed gas is provided prior to providing power to the plasma unit. In another example, while the plasma power is shown to be constant over a plasma power on period, in practice the plasma may comprise plurality of on-off cycles, where a percent duty or a duty cycle can be on-time/(on-time+off-time). Further, other embodiments of timing sequences that are not explicitly shown in FIGS. 2A-2D are possible and are not excluded from the disclosure. Where process steps are shown to be separate, an optional purging step may be performed between the steps. For example, an optional purging step may be performed between the Si-precursor pulse 226 and the plasma power pulse 224 in FIGS. 2C and 2D.

Returning to FIG. 1, in some embodiments, the low-k material film may be post processed 130 to improve one or more properties of the low-k material film. In other words, one or more post processing steps may be performed to improve one or more properties of the low-k material film. The one or more post processing steps may comprise one or more of UV curing, thermal anneal, and plasma treatment.

In some of these embodiments, the post processing step comprises irradiating the substrate comprising the low-k material film with UV radiation. The wavelength of the UV radiation typically ranges from at least about 100 nm to no more than about 400 nm, for example at least about 100 nm to no more than about 280 nm, or at least about 120 nm to no more than about 240 nm (e.g., vacuum UV). The UV radiation power may be between about 1 mW/cm² to about 1000 mW/cm2, typically about 10 mW/cm2, or about 50 mW/cm2, or about 100 mW/cm2, or about 200 mW/cm2, or about 500 mW/cm2, or about 1000 mW/cm2, or an value between any two numbers of the foregoing. Irradiating the substrate comprising the low-k material film may be performed at room temperature or at an elevated temperature. Preferably the step of irradiating the substrate comprising the low-k material film may be performed at an elevated temperature of at least about 40° C. to no more than about 500° C., typically the temperature of the substrate may be maintained at the same temperature or range of temperatures that the deposition process occurs at. Irradiating the substrate comprising the low-k material film may be performed over a time period of seconds, minutes, to hours, for example 30 sec., 1 min., 5 min, 10 min., 30 min., 60 min., and values between any two numbers of the foregoing. Further, in some embodiments, an inert gas may be provided to the reaction chamber during the irradiating or curing step to remove volatile products and/or reactive gasses from the surface of the substrate. UV curing the low-k material film may improve one or more properties of the film. For example, UV curing the low-k material film may increase the degree of crosslinking in the film and/or otherwise alter bond structure of the film. Additionally, or alternatively, UV curing may reduce the amount of carbon in the film and/or improve the electrical properties of the film.

In some of these embodiments, the post processing step comprises annealing the low-k material film. Annealing may be performed by heating the substrate comprising the low-k material film to an annealing temperature of at least about 300° C. to no more than about 1200° C. for a set period of time, typically at least about 400° C. to no more than about 600° C. The annealing may be performed at a reduced pressure. Additionally, or alternatively, the annealing may be performed in one or more of an inert environment (e.g., by flowing one or more of He, Ar, and N2 into the chamber) and a nitriding environment (e.g., by flowing NH3 and/or forming gas into the reaction chamber). The length of time of the anneal step may vary greatly, ranging from tenths of a second to hours, typically from minutes to hours. Further, more than one annealing step may be performed. Annealing the low-k material film may improve one or more properties of the film. For example, annealing the low-k material film may alter the composition of the film by removing impurities in the film and/or adding nitrogen to the film depending upon the annealing conditions. Additionally, or alternatively, annealing may increase the film density, reduce the wet etch rate (WER), and/or improve the electrical properties of the film.

In some of these embodiments, the post processing step comprises treating the low-k material film with a second plasma. The second plasma may be generated from feed gas comprising a noble gas (e.g., He, Ar, Ne, Kr, and Xe). Plasma treating may be performed while maintaining the substrate comprising the low-k material film at a temperature between about 50° C. and 500° C., or between about 100° C. to about 450° C., or between about 100° C. to about 400° C., or between about 100° C. to about 350° C., or between about 100° C. to about 325° C., or from about 100° C. to about 300° C., or from about 100° C. to about 275° C., or from about 100° C. to about 250° C., or from about 100° C. to about 200° C. In some embodiments, plasma treating is performed by maintaining the substrate comprising the low-k material film at the same temperature that the vapor deposition occurred at. In some embodiments, plasma treating is performed by maintaining the substrate comprising the low-k material film at a second temperature, while the vapor deposition is performed by maintaining the substrate at a first temperature. Plasma treating may typically be performed for a duration from 1 sec. to 10 min., or from 1 sec. to 1 min., or from 1 sec. to 10 sec. Plasma treating the low-k material film may improve one or more properties of the film. For example, plasma treating the low-k material film may increase the density of the film, improving the mechanical properties and/or reduce the WER.

Another aspect of the present disclosure relates to systems (e.g., a substrate processing apparatus) for forming a low-k material film on a surface of a substrate using the film forming compositions and the methods described in any of the above related paragraphs. The substrate processing apparatus may be a semiconductor processing apparatus. The substrate processing apparatus comprises at least one vapor deposition assembly. The vapor deposition assembly comprises at least one reaction chamber; a means for housing a substrate within the at least one reaction chamber; an optional supply of the hydrogen source and a means for introducing the optional hydrogen source into the reaction chamber; a supply of the film forming composition comprising the Si-precursor and a means for introducing a vapor of the film forming composition comprising the Si-precursor into the reaction chamber; and a means for generating a plasma within the reaction chamber.

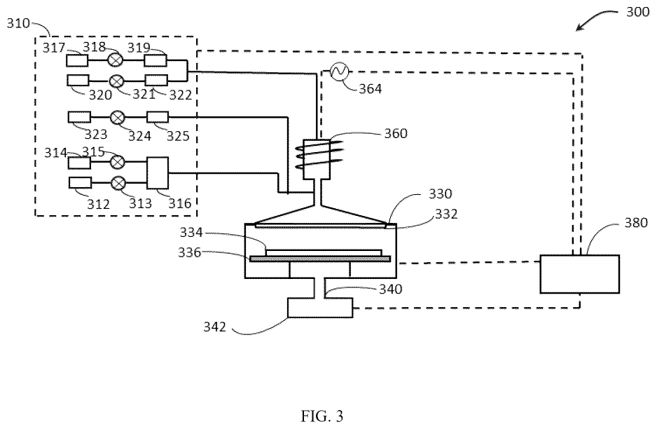

FIG. 3 shows a schematic diagram of an exemplary embodiment of a vapor deposition assembly 300 according to the present disclosure. The film forming composition comprising the Si-precursor, the optional hydrogen source, and other gases are provided into a reaction chamber 330 through an injector system 310. The injector system 310 is configured to provide the film forming composition from a film forming composition supply 312 (e.g., a precursor delivery vessel comprising the film forming composition) that is in fluid communication with the reaction chamber 330 via a film forming composition supply valve 313. The film forming composition comprising the Si-precursor may be provided from the film forming composition supply 312 in liquid form and vaporized in a vaporization unit 316 comprising a vaporizer and one or more mass flow controllers. A carrier gas flow may optionally be provided from a carrier gas supply 314 coupled to the vaporization unit 316 via a carrier gas supply valve 315. The injector system 310 may further be configured to provide a feed gas to a remote plasma unit 360 positioned upstream of the reaction chamber 330. For example, a hydrogen source may be provided from a hydrogen source supply 317 coupled to a hydrogen source supply valve 318 and a hydrogen source supply mass flow controller 319. Additionally, or alternatively, a feed gas, such as a noble gas or other reactive gas, may be provided from a feed gas supply 320 coupled to a feed gas supply valve 321 and a feed gas supply mass flow controller 322. The injector system 310 may further be configured to provide other gasses to the reaction chamber 330. For example, an optional purge gas may be provided from a purge gas supply 323 coupled to a purge gas supply valve 324 and a purge gas supply mass flow controller 325. The injector system 310 may further comprise a means for heating some or all of the various components, if required, to facilitate the introduction of the film forming composition and other gasses into the reaction chamber 330. The various gasses flow into the reaction chamber 330 though a gas distributor 332 (e.g., a showerhead) that is positioned over a substrate 334 that is seated on a susceptor 336. In some embodiments, the reaction chamber 330 further comprises one or more heating elements (not shown) that are in thermal communication with the substrate 334 and one or more thermocouples (not shown), to measure and maintain a temperature of the substrate 334 at set temperatures. Unreacted gasses and gaseous reaction by-products exit the reaction chamber 330 through an exhaust line 340 that is optionally coupled to one or more vacuum pumps 342. The optional one or more vacuum pumps may be used to maintain the reaction chamber 330 at a reduced pressure.

The vapor deposition assembly 300 comprises a remote plasma unit 360 positioned upstream of the reaction chamber 330. A plasma generator 364 (e.g., a RF power generator or microwave power generator) may be used to generate the plasma. By way of example, the remote plasma unit 360 can be an ICP or a microwave plasma unit. In some embodiments, the remote plasma unit 360 is an ICP. The remote plasma unit 360 can be used to delivery reactive plasma species (e.g., H radicals) to the reaction chamber for use in the vapor deposition process. However, due to spatial separation of the plasma from the substrate 334, the flux of ions, a potential source of film damage, to the underlying surface is minimized or prevented. Further, use of a remote plasma may preserve the structure of the Si-precursor so that certain structural elements of the Si-precursor are retained in the low-k material film.

The vapor deposition assembly 300 also comprises a controller 380 operably connected to the components of the injector system 310 (e.g., the film forming composition supply valve 313, the optional carrier gas supply valve 315, the vaporization unit 316, the optional hydrogen source supply valve 318, the optional hydrogen source supply mass flow controller 319, the optional feed gas supply valve 321, the optional feed gas supply mass flow controller 322, the optional purge gas supply valve 324, and the optional purge gas supply mass flow controller 325), the plasma generator 364, and other components. The controller 380 is configured and programmed to independently control (e.g., turn on and off, meter, etc.) the film forming composition supply 312, the optional carrier gas supply 314, the optional hydrogen source supply 317, the optional feed gas supply 320, the optional purge gas supply 323, the plasma generator 364, and other components, as required, to form a low-k material film on a surface of the substrate 334. For instance, the controller 380 may be configured and program to perform the process steps to form a low-k material film on a surface of the substrate 334 (e.g., as shown in 120 in FIGS. 1 and 201-204 in FIGS. 2A-D and discussed above).

In some embodiments, the controller 380 can be configured and programed to form a low-k material film on the surface of the substrate 334 by executing the timing sequences shown in FIG. 2A. For example, the controller 380 can be configured and programed to provide the feed gas to the reaction chamber 330, to optionally provide the hydrogen source into the reaction chamber 330, to provide the Si-precursor to the reaction chamber 330, and to provide the plasma to the reaction chamber 330. Next, after a set period of time, the controller 380 can be configured and programed to cease providing the hydrogen source into the reaction chamber 330 (if applicable), to cease providing the Si-precursor to the reaction chamber 330, and to cease providing the plasma to the reaction chamber 330. The controller 380 can be additionally programed to cease providing the feed gas to the reaction chamber 330. In other embodiments, the controller 380 can be configured and programed to form a low-k material film on the surface of the substrate 334 by executing the timing sequences shown in FIG. 2B. For example, the controller 380 can be configured and programed to provide the feed gas to the reaction chamber 330, optionally provide the hydrogen source into the reaction chamber 330 and to provide the plasma to the reaction chamber 330. The controller 380 can be configured and programed to next provide the Si-precursor to the reaction chamber 330, and after a set period of time, cease providing the Si-precursor to the reaction chamber 330. The steps of providing the Si-precursor and ceasing to provide the Si-precursor may be repeated one or more times. Finally, after another set period of time, the controller 380 can be configured and programed to cease providing the hydrogen source into the reaction chamber 330 (if applicable) and cease providing the plasma to the reaction chamber 330. The controller 380 can be additionally programed to cease providing the feed gas to the reaction chamber 330. In yet other embodiments, the controller 380 can be configured and programed to form a low-k material film on the surface of the substrate 334 by executing the timing sequences shown in FIG. 2C. For example, the controller 380 can be configured and programed to provide the feed gas to the reaction chamber 330 and optionally provide the hydrogen source into the reaction chamber 330. The controller can be further configured and programed to provide the Si-precursor to the reaction chamber 330, and after a set period of time, to cease providing the Si-precursor to the reaction chamber 330. Next, the controller 380 can be configured and programed to provide the plasma to the reaction chamber 330, and after a set period of time, to cease providing the plasma to the reaction chamber 330. The steps of providing the Si-precursor and ceasing to provide the Si-precursor and providing the plasma and ceasing to provide the plasma may be reversed. The steps of providing the Si-precursor and ceasing to provide the Si-precursor and providing the plasma and ceasing to provide the plasma may be repeated one or more times. Finally, after another set period of time, the controller 380 can be configured and programed to cease providing the feed gas into the reaction chamber 330 and to cease providing the hydrogen source into the reaction chamber 330 (if applicable). In yet other embodiments, the controller 380 can be configured and programed to form a low-k material film on the surface of the substrate 334 by executing the timing sequences shown in FIG. 2D. For example, the controller 380 can be configured and programed to provide the feed gas to the reaction chamber 330. Next, the controller 380 can be configured and programed to provide the Si-precursor to the reaction chamber 330, and after a set period of time, cease providing the Si-precursor to the reaction chamber 330. Next, the controller 380 can be configured and programed to optionally provide the hydrogen source the reaction chamber 330 and to provide the plasma to the reaction chamber 330, and after a set period of time, cease providing the hydrogen source to the reaction chamber 330 (if applicable), and cease providing the plasma to the reaction chamber 330. The steps of providing the Si-precursor and ceasing to provide the Si-precursor, optionally providing the hydrogen source and ceasing to provide the hydrogen source (if applicable), and providing the plasma and ceasing to provide the plasma may be repeated one or more times. The controller 380 can be additionally programed to cease providing the feed gas to the reaction chamber 330.

In these embodiments, the step of providing the silicon precursor to the reaction chamber 330 comprises turning on one or both of the film forming composition supply valve 313 and the vaporizer 316 to flow the film forming composition comprising the Si-precursor into the reaction chamber 330, whereas the step of ceasing to provide the silicon precursor to the reaction chamber 330 comprises turning off one or both of the film forming composition supply valve 313 and the vaporizer 316 to cease flowing the film forming composition comprising the Si-precursor into the reaction chamber 330. The step of providing the feed gas to the reaction chamber 330 comprises turning on one or both of the feed gas supply valve 321 and the feed gas mass flow controller 322, whereas the step of ceasing to provide the feed gas to the reaction chamber 330 comprises turning off one or both of the feed gas supply valve 321 and the feed gas supply mass flow controller 322. The step of providing the hydrogen source to the reaction chamber 330 comprises turning on one or both of the hydrogen source supply valve 318 and the hydrogen source supply mass flow controller 319, whereas the step of ceasing to provide the hydrogen source to the reaction chamber 330 comprises turning off one or both of the hydrogen source supply valve 318 and the hydrogen source supply mass flow controller 319. The hydrogen source may be provided to the reaction chamber 330 by flowing the hydrogen source, along with the feed gas, through the plasma unit 360 to the reaction chamber 330. The hydrogen source may be a component of the feed gas or provided with the feed gas or it may be the feed gas. In these embodiments, the step of providing the plasma to the reaction chamber 330 comprises turning on the plasma generator 364 to apply a plasma power to the plasma unit 360, whereas the step of ceasing to provide the plasma to the reaction chamber 330 comprises turning off the plasma generator 364 to end the plasma power to the plasma unit 360.

As will be appreciated by one of skill in art, other vapor deposition assembly configurations are possible. For example, although the injection system 310 and reaction chamber 330 are shown and described herein as having a specific structure and flow configuration, other flow configurations and/or other mechanisms for providing the various reactants and gases to the reaction chamber 330 and for housing the substrate 334 and flowing gasses over the substrate 334 may be utilized. For example, the reaction chamber 330 may be configured in a cross-flow configuration, where one or more of the Si-precursor and other gasses are flow across the substrate surface. Additionally, other plasma generation configurations may be utilized. In some embodiments, the plasma may be formed in the reaction chamber 330. For example, a plasma may be formed in the reaction chamber 330 by biasing the gas distributor 332 relative to the susceptor 336. A remote plasma may be formed by positioning an ion trap between the distributor 332 and the susceptor 336. Additionally, the vapor deposition assembly may comprise a number of other components that are not explicitly shown in FIG. 3. Further, the controller may be configured and programed to perform a number of other operations not explicitly discussed here and/or perform the operations in another order than discussed here and/or omit some of the operations discussed here.

In some embodiments, the substrate processing apparatus comprises more than one vapor deposition assembly. Additionally, or alternatively, the substrate processing apparatus may further comprise a post processing assembly. For example, the substrate processing apparatus may further comprise one or both of a UV curing assembly and an annealing assembly. The substrate may be transferred to the post processing assembly after a low-k material film is deposited on the surface of the substrate in the vapor deposition assembly 300.

In some embodiments, the substrate processing apparatus comprises one or more post processing assemblies comprising a UV curing assembly. The UV curing assembly may comprise a curing chamber comprising a susceptor and one or more UV lamps. The one or more UV lamps typically produce radiation in the range of at least about 100 nm to no more than about 400 nm, typically at least about 100 nm to no more than about 280 nm, or at least about 120 nm to no more than about 240 nm (e.g., vacuum UV). The UV radiation power may be between about 1 mW/cm² to about 1000 mW/cm2, typically 10 mW/cm2, or 50 mW/cm2, or 100 mW/cm2, or 200 mW/cm2, or 500 mW/cm2, or 1000 mW/cm² and value between any two numbers of the foregoing. The UV curing assembly may further optionally comprise one or more heating elements that are in thermal communication with the substrate, positioned on the susceptor, and one or more thermocouples, to measure and maintain a temperature of the substrate at set temperatures. The UV curing assembly may further optionally comprise one or more gas inlets for flowing a gas (e.g., an inert gas) into the curing chamber while the substrate is irradiated.

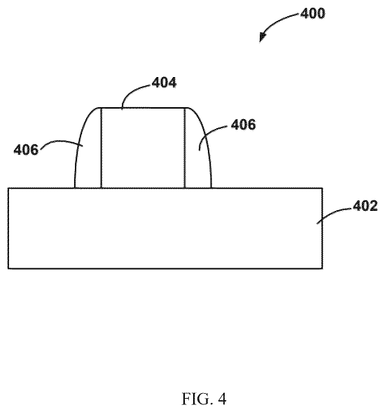

Another aspect of the present disclosure relates to structures comprising the low-k material film that is formed using the film forming compositions comprising the Si-precursor and the methods and systems described in any of the above related paragraphs. Example structures may comprise spacers comprising the low-k material film suitable for use in formation of three-dimensional device structures used in the formation of, for example, FinFET and gate-all-around devices. FIG. 4 illustrates a structure formed in accordance with examples of the disclosure. Structure 400 includes a substrate 402, a feature 404, and spacer 406. The substrate 402 can be or include any substrate described herein. The feature 404 can include a metallic, semiconductive, or dielectric patterned feature. The spacer 406 can be formed by depositing a low-k material layer according to methods disclosed herein (e.g., see 100 in FIG. 1) and using the systems disclosed herein, and then removing a portion of the layer in one or more subsequent processing steps.

The disclosed film forming compositions and the methods and the systems for using said film forming compositions to form a low-k material film may provide several benefits. Without wishing to be bound to any particular theory, the structure of Si-precursor in the film forming composition may advantageously impact the low-k material film properties. The oxygen in the Si-precursor contributes to the oxygen content of the low k material film, and thus the film may be formed without the use of an oxygen plasma (e.g., O2 plasma) which may damage the underlying surface. The presence of the one or more optionally substituted vinyl group(s) on the Si-precursor contributes to the crosslinking of the low-k material film. Hence, the resulting low-k material film may comprise Si—C—Si and/or Si—C—C—Si bonds within the film. The degree of crosslinking of the film can be increased by reaction of the optionally substituted vinyl group(s) with H radicals. The increased degree of crosslinking in the film may increase the mechanical strength and toughness of the low-k material film as well as the thermal stability and chemical resistance of the film. In some embodiments, the presence of alkyl groups on the at least one silicon atom increases the carbon content of the film. Carbon incorporation into the low-k material film helps lower the dielectric constant of the film. In some embodiments, the cyclic structure of the Si-precursor may contribute to the porosity of the low-k material film. Under certain conditions the ring structure may be preserved in the film. Use of the remote plasma may help ensure that the ring structure remains intact, essentially intact, or partially intact in the film. Increasing porosity generally lowers the dielectric constant of the film. The combination of the structure features of the Si-precursor and process conditions can provide a film with a high deposition rate, a low k value, a low WER, low electrical leakage, and good mechanical and thermal properties. The structure features of the Si-precursor may be selected to tune or optimize the properties of the low-k material film.

In certain embodiments, the low-k material film may have a low dielectric constant. For example, in some embodiments, the low-k material film has a dielectric constant of less than about 3.8, or less than about 3.5, or less than about 3.4, or less than about 3.3, or less than about 3.2, or less than about 3.1, or less than about 3.0, or less than about 2.9, or less than about 2.8, or less than about 2.7, or less than about 2.6, or less than about 2.5, or less than about 2.4, or less than about 2.3, or less than about 2.2, or less than about 2.1, or less than about 2.0. Further, in some embodiments, the low-k material film may also have good mechanical performance. For example, in some embodiments, the low-k material film with a dielectric constant of less than about 3.8 may also have a wet etch rate (WER) of less than 1 nm/min in 1% dilute hydrofluoric acid, or less than 0.9 nm/min in 1% dilute hydrofluoric acid, or less than 0.8 nm/min in 1% dilute hydrofluoric acid, or less than 0.7 nm/min in 1% dilute hydrofluoric acid, or less than 0.6 nm/min in 1% dilute hydrofluoric acid, or less than 0.5 nm/min in 1% dilute hydrofluoric acid, or less than 0.4 nm/min in 1% dilute hydrofluoric acid, or less than 0.3 nm/min in 1% dilute hydrofluoric acid, or less than 0.2 nm/min in 1% dilute hydrofluoric acid, or less than 0.1 nm/min in 1% dilute hydrofluoric acid. In some embodiments, the low-k material film may also have good conformality even over very narrow features (e.g., CD≤20). For example, in some embodiments, the low-k material film has a step coverage of about 80% or more, or about 90% or more. In some embodiments, the carbon doped silicon containing film has a step coverage of about 90% more and less than about 110%, or about 95% or more and less than about 105%.

Although certain embodiments and examples are disclosed herein, it will be understood by those skilled in the art that the disclosed compositions, methods, systems, and structures extend beyond the specifically disclosed embodiments and include all novel and nonobvious combinations and sub-combinations of the various compositions, methods, systems, and structures as well as any and all equivalents thereof. It is to be understood that the compositions, methods, systems, and structures described herein are exemplary in nature, and that these specific embodiments or examples are not to be considered in a limiting sense, because numerous variations are possible. The specific methods and systems described herein may represent one or more of any number of processing strategies. Thus, the various acts illustrated may be performed in the sequence illustrated, in other sequences, or omitted in some cases. Moreover, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. The compositions, methods, systems, and structures of the disclosure are not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate embodiment of the disclosure, and the features recited in the various dependent claims may be combined with one another in various combinations, as appropriate, to form other embodiment of the disclosure.

1. A method for forming a low-k material layer on a surface of a substrate, the method comprising:
providing the substrate in a reaction chamber; and
forming the low-k material layer on the surface of the substrate using a vapor deposition process comprising:
providing a Si-precursor to the reaction chamber, wherein the Si-precursor comprises at least one silicon atom that is bonded to an oxygen atom and to an optionally substituted vinyl group;
providing a hydrogen source to the reaction chamber; and
providing a plasma to the reaction chamber.

2. The method according to claim 1, wherein the Si-precursor has a structure according to a general formula (2): 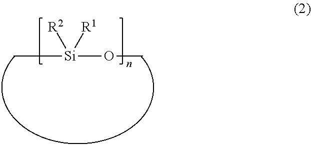
wherein n is an integer selected from 2, 3, 4, or 5; each R1 is independently the optionally substituted vinyl group; and each R2 is independently selected from the group consisting of an H atom, a C1-C6 alkyl group, and a second optionally substituted vinyl group.

3. The method according to claim 2, wherein each R2 is selected from an H atom or a C1-C6 alkyl group.

4. The method according to claim 2, wherein the Si-precursor is selected from the group consisting of 1,3-divinylcyclodisiloxane, 1,3-dimethyl-1,3-divinylcyclodisiloxane, 1,3-diethyl-1,3-divinylcyclodisiloxane, 1,1,3,3-tetravinylcyclodisiloxane, 1,3,5-trivinylcyclotrisiloxane, 1,3,5-trimethyl-1,3,5-trivinylcyclotrisiloxane, 1,3,5-triethyl-1,3,5-trivinylcyclotrisiloxane, 1,1,3,3,5,5-hexavinylcyclotrisiloxane, 1,3,5,7-tetravinylcyclotetrasiloxane, 1,3,5,7-tetramethyl-1,3,5,7-tetravinylcyclotetrasiloxane, 1,3,5,7-tetraethyl-1,3,5,7-tetravinylcyclotetrasiloxane, 1,1,3,3,5,5,7,7-octavinylcyclotetrasiloxane, 1,3,5,7,9-pentavinylcyclopentasiloxane, 1,3,5,7,9-pentamethyl-1,3,5,7,9-pentavinylcyclopentasiloxane, 1,3,5,7,9-pentaethyl-1,3,5,7,9-pentavinylcyclopentasiloxane, and 1,1,3,3,5,5,7,7,9,9-decavinylcyclopentasiloxane.

5. The method according to claim 1, wherein the Si-precursor has a structure according to a general formula (1): 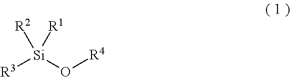
wherein R1 is the optionally substituted vinyl group; R2 is selected from the group consisting of an H atom, a C1-C6 alkyl group, and a second optionally substituted vinyl group; R3 is selected from the group consisting of an H atom and a C1-C6 alkyl group; and R4 is selected from the group consisting of a C1-C6 alkyl group and a C2-C6 alkenyl group.

6. The method according to claim 5, wherein R2 is selected from the group consisting of an H atom and a C1-C6 alkyl group; R3 is selected from the group consisting of an H atom and a C1-C6 alkyl group; and R4 is a C1-C6 alkyl group.

7. The method according to claim 5, wherein the Si-precursor is selected from the group consisting of ethenylmethoxysilane, ethenylethoxysilane, ethenylmethoxymethylsilane, ethenylethoxymethylsilane, ethenylethoxyethylsilane, ethenylethoxydimethylsilane, ethenylethoxydiethylsilane, diethenylmethoxysilane, diethenylethoxysilane, diethenylmethoxymethylsilane, and diethenylethoxymethylsilane.

8. The method according to claim 1, wherein the hydrogen source comprises one or more of hydrogen (H2), an N—H bond containing reactant, and an Si—H bond containing reactant.

9. The method according to claim 1, wherein the hydrogen source comprises a mixture of hydrogen gas (H2) and a noble gas.

10. The method according to claim 1, wherein the vapor deposition process is a cyclic deposition process, wherein the step of providing the Si-precursor to the reaction chamber comprises pulsing the Si-precursor into the reaction chamber.

11. The method according to claim 1, wherein the step of providing the hydrogen source to the reaction chamber at least partially overlaps with the step of providing the plasma to the reaction chamber.

12. The method according to claim 1, wherein the step of providing the Si-precursor to the reaction chamber at least partially overlaps with the step of providing the plasma to the reaction chamber.

13. The method according to claim 1, wherein the step of providing the Si-precursor to the reaction chamber is separate from the step of providing the plasma to the reaction chamber.

14. The method according to claim 1, wherein the plasma is a remote plasma.

15. The method according to claim 1, wherein the method further comprises maintaining a temperature of the substrate at least about 50° C. and no more than about 500° C., preferably at least about 75° C. and no more than about 250° C., preferably at least about 100° C. and no more than about 200° C.

16. The method according to claim 1, wherein the method further comprises maintaining the reaction chamber at a pressure of at least about 0.5 Torr and no more than about 100 Torr, preferably at least about 1 Torr and no more than about 10 Torr.

17. The method according to claim 1, wherein the low-k material layer comprises a carbon content of at least about 5 at. % and no more than about 60 at. %, preferably at least about 10 at. % and no more than about 50 at. %.

18. The method according to any one of claim 1, wherein the method further comprises, after the vapor deposition process, one or more of irradiating the low k material layer with UV radiation, treating the low k material layer with a plasma, and annealing the low k material layer.

19. A substrate processing apparatus for forming a low k material layer on a surface of a substrate according to the method of claim 1.

20. A structure comprising a low-k material layer, wherein the low-k material layer is formed according to the method of claim 1.
